(19) United States
(12) Patent Application Publication
(10) Pub. No.: US 2010/0195420 A1
(43) Pub. Date: Aug. 5, 2010

(54) SEMICONDUCTOR MEMORY DEVICE AND SYSTEM

(76) Inventors: Sung-dong SUH, Seoul (KR); Seong-gu Kim, Pyeongtaek-si (KR); Kyoung-ho Ha, Seoul (KR); Soo-haeng Cho, Suwon-si (KR)

Correspondence Address: F. CHAU & ASSOCIATES, LLC, 130 WOODBURY ROAD, WOODBURY, NY, 11797, US

(21) Appl. No.: 12/689,040

(22) Filed: Jan. 18, 2010

(30) Foreign Application Priority Data
Feb. 3, 2009 (KR) 10-2009-0008384

(51) Int. Cl. G11C 7/00

(52) U.S. Cl. 365/191; 365/189.11

(57) ABSTRACT

A semiconductor memory system includes a memory controller and a memory. The memory controller includes a control signal converting unit converting a control signal into a converted control signal including n sequential clock pulses and a target clock pulse activated after a time period has elapsed from a start point of the n sequential clock pulses, and output the converted clock signal, and a controller transmitting unit converting the converted control signal into an optical signal, and transmitting the optical signal to the memory. The memory includes a memory receiving unit converting the optical signal into an electrical signal, and a control signal re-converting unit detecting the time period from the electrical signal, and converting the control signal into a control signal corresponding to the time period.

### CROSS-REFERENCE TO RELATED APPLICATIONS

This application claims priority to Korean Patent Application No. 10-2009-0008384, filed on Feb. 3, 2009, in the Korean Intellectual Property Office, the disclosure of which is incorporated by reference in its entirety herein.

### BACKGROUND

1. Technical Field

Embodiments of the inventive concept relate to a semiconductor device and system, and more particularly, to a semiconductor memory system that provides an optical signal as a control signal to a memory.

2. Discussion of Related Art

A memory system may include a semiconductor memory device and a memory controller. The semiconductor memory device stores data or outputs the stored data in response to a control signal applied from the memory controller. The memory system may perform a test for all memory cells of the semiconductor memory device during a test operation to identify an address of a normal memory cell and an address of a defective memory cell.

However, errors may occur in the communication of the control signals from the memory controller to the semiconductor memory device. For example, the memory controller may apply an inappropriate control signal, or noise may corrupt the control signals during transmission. Such errors may cause an abnormal operation of the semiconductor memory device, resulting in poor performance of the memory system.

Thus, there is need for a semiconductor memory device or system that can correctly transmit a control signal to the memory.

### SUMMARY

A semiconductor memory system according to an exemplary embodiment of the inventive concept includes a memory controller and a memory. The memory controller includes a control signal converting unit converting a control signal into a converted control signal including n sequential clock pulses, and a target clock pulse which is activated after a time period has elapsed from a start point of the n sequential clock pulses, and outputting the converted control signal, and a controller transmitting unit converting the converted control signal into an optical signal, and transmitting the optical signal to the memory. The memory includes a memory receiving unit converting the optical signal into an electrical signal, and a control signal re-converting unit detecting the time period from the electrical signal, and converting the electrical signal into a control signal corresponding to the time period.

The control signal may be one of a column address signal (CAS) to address columns of the memory or a row address signal (RAS) to address rows of the memory. The memory controller may further include a memory control unit (MCU) or a field programmable gate array (FPGA), which generates the control signal. The memory controller may transmit the control signal to the memory to test the memory. The memory receiving unit may include a voltage level translator to convert a voltage level of the electrical signal into an operation voltage level of the memory. The time period may be a first value when the control signal is a CAS signal and a second and different value then the control signal is a RAS signal. The control signal re-converting unit may include a control signal conversion table including respective entries for the CAS signal and the RAS signal and their respective time periods. The number of sequential clock pulses may be the same for the RAS signal and the CAS signal. The memory controller and the memory may be connected to each other via a waveguide. The control signal converting unit and the control signal re-converting unit may be FPGAs.

A computing system according to an exemplary embodiment of the inventive concept includes a memory system having a control signal converting unit, a controller transmitting unit, a memory receiving unit, and a control signal re-converting unit. The control signal converting unit is configured to convert a control signal into a converted control signal including n sequential clock pulses, and a target clock which is activated after the n sequential clock pulses have elapsed, and output the converted control signal. The controller transmitting unit is configured to convert the converted control signal into an optical signal, and transmit the optical signal to the memory. The memory receiving unit is configured to convert the optical signal into an electrical signal. The control signal re-converting unit is configured to detect the time period from the electrical signal, and convert the electrical signal into a control signal corresponding to the time period.

The computing system may further include a central processing unit (CPU), a user interface, a power supply, and a bus, where the memory system, CPU, user interface, and power supply are connected to the bus.

A memory device according to an exemplary embodiment of the inventive concept includes a memory receiving unit configured to convert an optical signal including a sinusoidal part into an electrical signal, the optical signal including n starting bits indicated as n sequential clocks and a target clock activated after a time period has elapsed from a start point of the starting bits, and a control signal re-converting unit configured to detect the time period from electrical signal, and convert the electrical signal into a control signal corresponding to the time period.

### BRIEF DESCRIPTION OF THE DRAWINGS

Exemplary embodiments of the inventive concept will be more clearly understood from the following detailed description taken in conjunction with the accompanying drawings in which:

FIG. 1 is a block diagram of a semiconductor memory system according to an embodiment of the inventive concept;

FIG. 2A, FIG. 2B, FIG. 2C, and FIG. 2D are exemplary graphs for respectively illustrating signal patterns of signals which may be generated by a memory control unit of FIG. 1;

FIG. 3A, FIG. 3B, and FIG. 3C illustrate simulation results from a comparison between a signal transmitted from a memory controller of FIG. 1 and a signal received by a memory of FIG. 1;

FIG. 4A, FIG. 4B, and FIG. 4C illustrate signal waveforms of the signal received by the memory of FIG. 1, which respectively correspond to the simulation results of FIG. 3A, FIG. 3B, and FIG. 3C;

FIG. 5 is a diagram for describing a control signal converted by a control signal converting unit and a control signal re-converting unit of FIG. 1;

FIG. 6 is a diagram illustrating signal lines respectively of a clock signal and a control signal of FIG. 1;

FIG. 7 is a diagram of an exemplary embodiment of a control signal conversion table of FIG. 1; and

FIG. 8 is a block diagram of a computing system including the semiconductor memory system of FIG. 1 according to an exemplary embodiment of the inventive concept.

### DETAILED DESCRIPTION OF EXEMPLARY EMBODIMENTS

Hereinafter, the inventive concept will be described in detail by describing exemplary embodiments thereof with reference to the attached drawings. Like reference numerals in the drawings denote like elements.

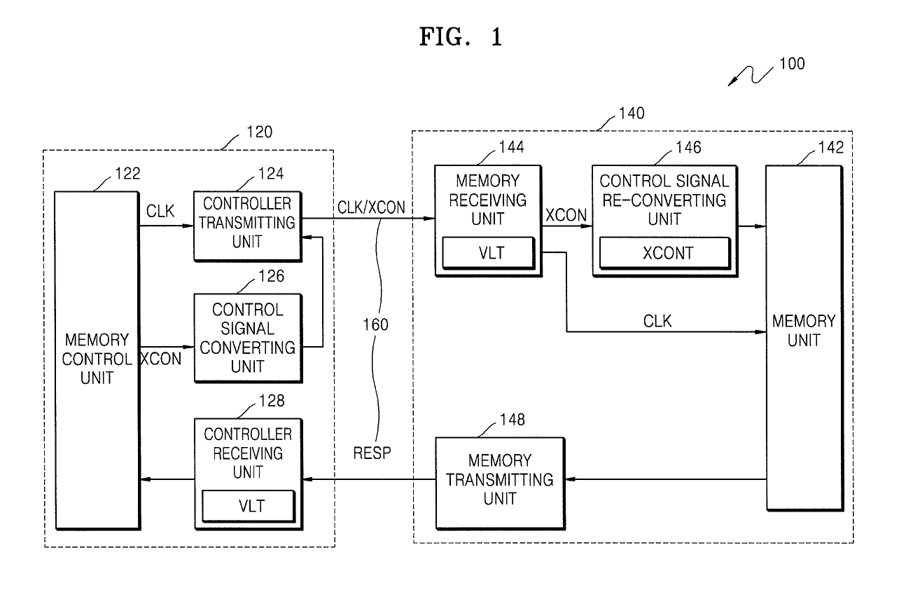

FIG. 1 is a block diagram of a semiconductor memory system 100 according to an exemplary embodiment of the inventive concept. Referring to FIG. 1, the semiconductor memory system 100 includes a memory controller 120 and a memory 140. The memory controller 120 includes a memory control unit 122, a controller transmitting unit 124, a control signal converting unit 126, and a controller receiving unit 128. The memory controller 120 may transmit signals to the memory 140 to control the memory 140. The signals, which are transmitted from the memory controller 120 to the memory 140, may be a clock signal CLK and a control signal XCON. The control signal XCON may have various different states such as an active high state, an active low state, a high state, and a low state. The clock signal CLK and the control signal XCON may be transmitted from the memory controller 120 to the memory 140 to test the memory 140.

The memory control unit 122 of the memory controller 120 may generate the signals. The memory control unit 122 may be a memory control unit (MCU) or a field programmable gate array (FPGA).

The controller transmitting unit 124 of the memory controller 120 may transmit the signals generated by the memory control unit 122 to the memory 140. The controller transmitting unit 124 may be configured to convert the clock signal CLK and the control signal XCON into optical signals and may transmit the optical signals to the memory 140.

The controller receiving unit 128 of the memory controller 120 may be configured to receive a response signal RESP that is transmitted from the memory 140 in response to the control signal XCON, and may convert the response signal RESP, which is an optical signal, into one or more electrical signals (e.g., a clock signal CLK and a control signal XCON) capable of operating the memory control unit 122. The controller receiving unit 128 may include a voltage level translator (VLT) that converts a voltage level of the clock signal CLK and the control signal XCON, which are converted into electrical signals, into an operation voltage level of the memory controller 120.

In this manner, the memory controller 120 and the memory 140 may transfer signals between one another via an optical communication. A bus 160 (e.g., embodied as a waveguide) may be disposed between the memory controller 120 and the memory 140 to enable the exchange of optical signals therebetween. For example, the waveguide may be an optical link, an optical fiber, a polymer waveguide, etc. The bus 160 may be implemented as part of an optical printed circuit board (PCB), which can transmit light without dispersion.

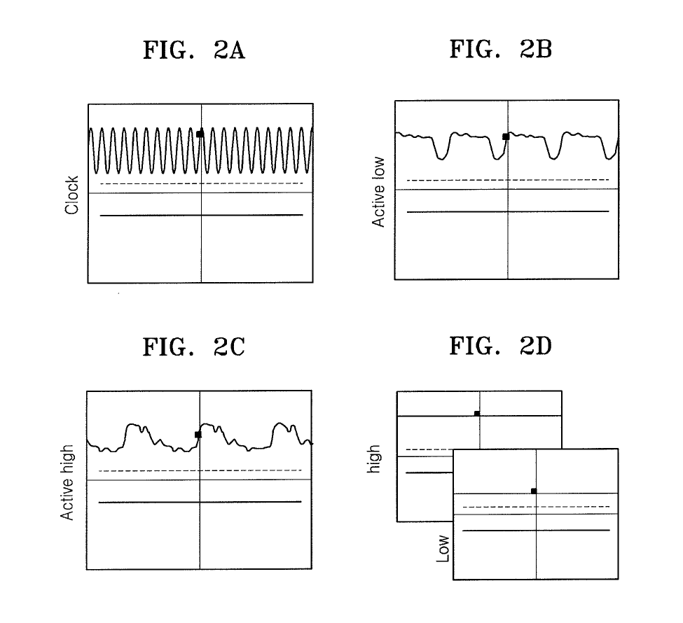

FIGS. 2A-2D illustrate example signal patterns of the clock signal CLK, and the control signal XCON in the active high state, the active low state, the high state, and the low state FIG. 2.

Referring to FIG. 2A, the clock signal CLK has a sinusoidal shape. Referring to FIGS. 2B-D, the control signal XCON, which is in the active high state, the active low state, the high state, and the low state, does not have a sinusoidal shape.

However, the control signal XCON needs to have a sinusoidal shape to be transmitted from the memory controller 120 to the memory 140 using an optical link such as the bus 160 of FIG. 1. For example, in optical communication, information is delivered using light that is converted into a beam having a sinusoidal shape.

When the control signal XCON is transmitted without a sinusoidal shape by using optical communication, a signal distortion phenomenon may occur due to noise, etc. Moreover, since the control signal XCON has a long period, as compared to the clock signal CLK, such a signal distortion phenomenon may become serious.

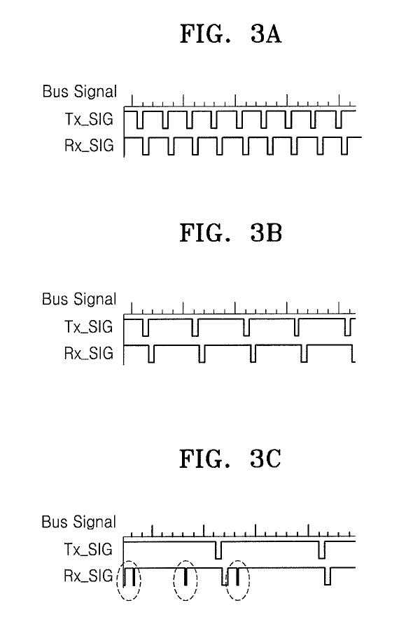

Noise included in the control signal XCON transmitted from the memory controller 120 to the memory 140 increases as pulse duty decreases, as illustrated in FIGS. 3A-C, which show a simulation result comparing a signal Tx_SIG transmitted from the memory controller 120 with a signal Rx_SIG received by the memory 140. The noise is indicated as a thick line in FIG. 3C.

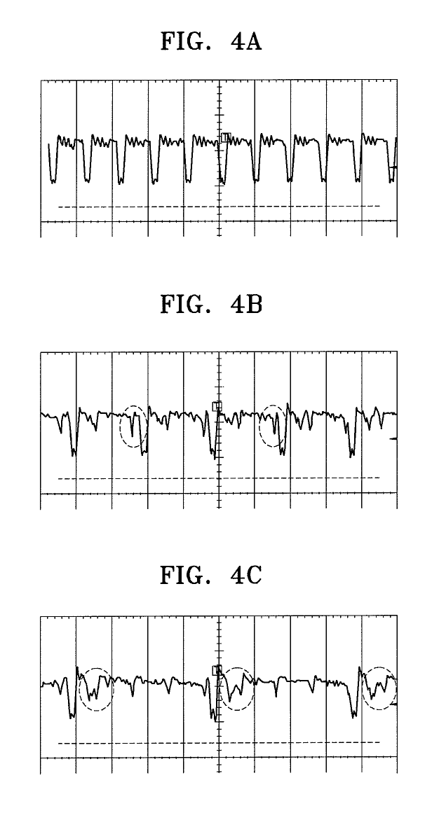

As illustrated in FIG. 4A, FIG. 4B, and FIG. 4C, which show a signal waveform of the control signal XCON received by the memory 140, which correspond to the simulation results of FIGS. 3A-C, if the noise is generated to have an amplitude greater than a reference value (refer to dashed circles in FIG. 4B and FIG. 4C), the noise may be erroneously recognized as data or a signal.

Referring back to FIG. 1, the control signal converting unit 126 of the memory controller 120 is configured to convert the control signal XCON into a signal in the form of the clock signal CLK (hereinafter, referred to as ‘clock signal-shaped signal’), which may prevent signal the signal distortion phenomenon due to optical conversion of the control signal XCON. For example, the control signal converting unit 126 may be embodied as an FPGA.

The control signal converting unit 126 may convert the control signal XCON such that it includes one or more starting bits and a target clock. The starting bits may correspond to n (e.g., 0 or more) sequential clock pulses. The target clock is activated after a first time has elapsed from a start point of the starting bits. The first time may correspond to the period of the n sequential clock pulses or the period of the n sequential clock pulses plus an additional period.

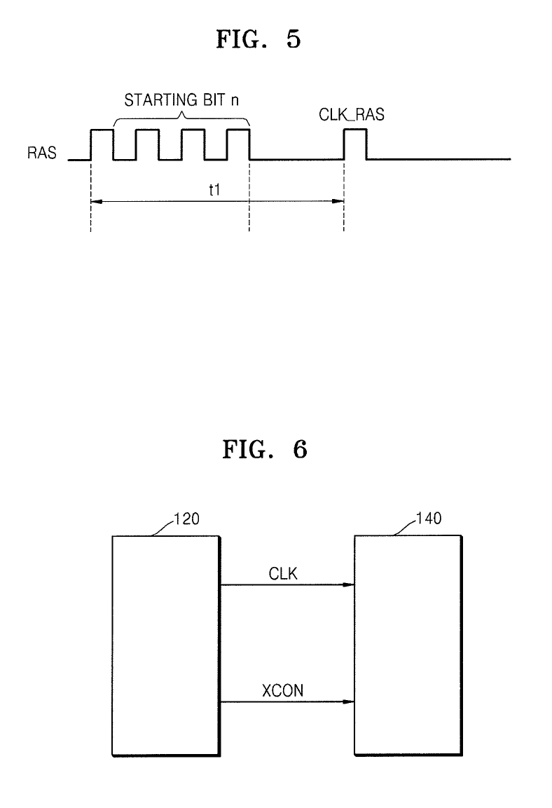

For example, the control signal XCON may be converted in a manner as shown in FIG. 5. Referring to FIGS. 1 and 5, the control signal converting unit 126 may convert a row address signal (RAS) signal, which is a type of the control signal XCON used to address rows of the memory unit 142, into starting bits and a target clock CLK_RAS that is activated after a first time t1 has elapsed from a start point of the starting bits.

The control signal converting unit 126 may vary the first time t1 according to control signals to be converted, and thus may set the first time t1. For example, the first time t1 with respect to the RAS signal may be 1 and the first time t1 with respect to a column address signal (CAS) signal (e.g., another type of control signal XCON used to address columns of the memory unit 142) may be 2. However, the number of clock pulses n of the starting bits for each of the different control signals may be set to the same value.

The control signal XCON, which is converted into the clock signal-shaped signal as illustrated in FIG. 5, is converted into an optical signal by the controller transmitting unit 124 and then is transmitted to the memory 140. Referring to FIG. 1, for convenience of illustration, the clock signal CLK and the control signal XCON use the same signal line. However, as illustrated in FIG. 6, the clock signal CLK and the control signal XCON may be transmitted and received via exclusive signal lines, respectively.

The semiconductor memory system 100 according to the embodiment of FIG. 1 may convert the control signal XCON into the clock signal-shaped signal having a sinusoidal waveform appropriate for optical communication, may transmit the clock signal-shaped signal to the memory 140, and thus may prevent the signal distortion phenomenon as illustrated in FIGS. 3A-C and 4A-C.

Referring back to FIG. 1, the memory 140 for receiving the clock signal CLK and the control signal XCON from the memory controller 120 includes a memory receiving unit 144, a control signal re-converting unit 146, a memory unit 142, and a memory transmitting unit 148.

The memory receiving unit 144 receives the clock signal CLK and the control signal XCON. The memory receiving unit 144 may convert the clock signal CLK and the control signal XCON, which are received in the form of optical signals, into electrical signals that can be recognized by the memory 140. The memory receiving unit 144 may include a VLT that converts voltage levels of the clock signal CLK and the control signal XCON, which are converted into the electrical signals, into an operation voltage level of the memory 140.

The memory receiving unit 144 performs optical-electrical conversion on the clock signal CLK, and then transmits the clock signal CLK to the memory unit 142. The memory receiving unit 144 performs optical-electrical conversion on the control signal XCON, and then transmits the control signal XCON to the memory unit 142. The control signal re-converting unit 146 may convert the control signal XCON into a control signal corresponding to the first time t1 of the clock signal-shaped signal converted into the electrical signal by the memory receiving unit 144 as illustrated in FIG. 5. The control signal re-converting unit 146 may sequentially receive a control signal XCON including n clock pulses, may recognize the n clock pulses as starting bits, and thus may detect the first time t1 that corresponds to a time period from a start point of the starting bits to a point at which a target clock CLK_RAS is activated.

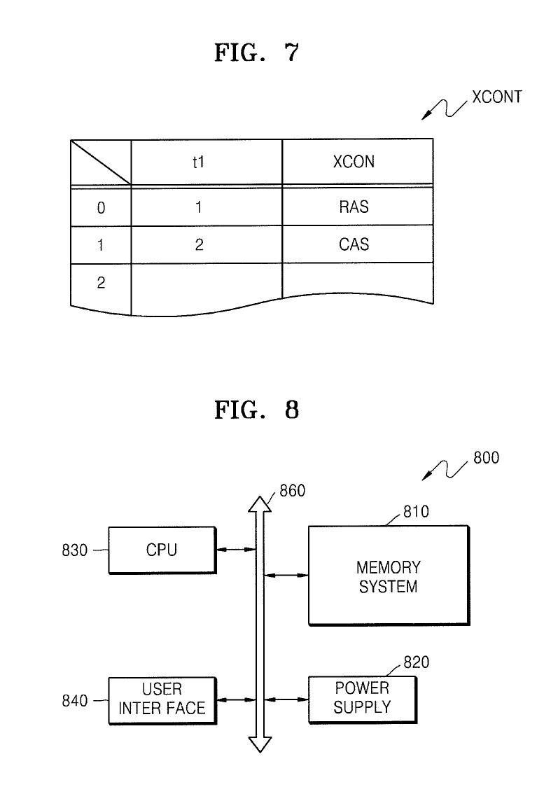

The control signal re-converting unit 146 may include a control signal conversion table XCONT for a control signal XCON corresponding to the detected first time t1. As illustrated in FIG. 7, the control signal re-converting unit 146 may include the control signal conversion table XCONT storing entries for each signal type and its corresponding first time t1. For example, a 0th index entry of the table XCONT may include an entry specifying a RAS signal type and a first time t1 of 1 (e.g., second, ms, etc.), and a 1^{st} index entry of the table XCONT may include an entry specifying a CAS signal type and a first time t1 of 2 (e.g., second ms, etc.). The control signal re-converting unit 146 may be an FPGA.

The semiconductor memory system 100 according to the embodiment of FIG. 1 may convert the control signal XCON into a clock signal having a sinusoidal shape, may exchange the converted control signal XCON via optical communication, and thus may prevent the control signal distortion phenomenon due to noise. Also, since the control signal XCON having a longer period as compared to the clock signal CLK, is converted into a control signal having a clock waveform and then is transmitted, a desired bandwidth may be achieved.

Referring back to FIG. 1, the memory unit 142 may include a memory cell array (not shown), a write/read driver (not shown) and a sense amplifier (not shown). The memory unit 142 may receive the clock signal CLK and the control signal XCON, synchronize the control signal XCON with the clock signal CLK, and perform an operation corresponding to the control signal XCON.

The response signal RESP, from the memory unit 142 and which corresponds to the control signal XCON, is converted into an optical signal via the memory transmitting unit 148 and then is transmitted to the memory controller 120.

FIG. 8 is a block diagram of a computing system 800 including a semiconductor memory system 810 as the semiconductor memory system 100 of FIG. 1 according to an exemplary embodiment of the inventive concept. Referring to FIG. 8, the computing system 800 includes a microprocessor 830 electrically connected to a bus 860, a user interface 840, and a power supply device 820.

While the inventive concept have been particularly shown and described with reference to exemplary embodiments thereof, it will be understood that various changes in form and details may be made therein without departing from the spirit and scope of the disclosure.

What is claimed is:

1. A semiconductor memory system comprising a memory controller and a memory,
wherein the memory controller comprises:
a control signal converting unit configured to convert a control signal into a converted control signal including n sequential clock pulses, and a target clock pulse which is activated after a time period has elapsed from a start point of the n sequential clock pulses, and output the converted control signal; and
a controller transmitting unit configured to convert the converted control signal into an optical signal, and transmit the optical signal to the memory, and wherein the memory comprises:
a memory receiving unit configured to convert the optical signal into an electrical signal; and
a control signal re-converting unit configured to detecting the time period from the electrical signal, and convert the electrical signal into a control signal corresponding to the time period.

2. The semiconductor memory system of claim 1, wherein the control signal is one of a column address signal to address columns of the memory or a row address signal to address rows of the memory.

3. The semiconductor memory system of claim 1, wherein the memory controller further comprises one of a memory control unit (MCU) or a field programmable gate array (FPGA), which generates the control signal.

4. The semiconductor memory system of claim 1, wherein the memory controller transmits the control signal to the memory to test the memory.

5. The semiconductor memory system of claim 1, wherein the memory receiving unit comprises a voltage level translator configured to convert a voltage level of the electrical signal into an operation voltage level of the memory.

6. The semiconductor memory system of claim 2, wherein the time period is a first value when the control signal is a CAS signal and a second and different value when the control signal is a RAS signal.

7. The semiconductor memory system of claim 2, wherein the control signal re-converting unit comprises a control signal conversion table including respective entries for the CAS signal and the RAS signal and their respective time periods.

8. The semiconductor memory system of claim 2, wherein n is the same for the CAS signal and RAS signal.

9. The semiconductor memory system of claim 1, wherein the memory controller and the memory are connected to each other via a waveguide.

10. The semiconductor memory system of claim 1, wherein the control signal converting unit and the control signal re-converting unit are FPGAs.

11. A computing system comprising:
a memory system comprising:
a control signal converting unit configured to convert a control signal into a converted control signal including n sequential clock pulses, and a target clock pulse which is activated after the n sequential clock pulses have elapsed, and output the converted control signal;
a controller transmitting unit configured to convert the converted control signal into an optical signal, and transmit the optical signal to the memory, and
a memory receiving unit configured to convert the optical signal into an electrical signal; and
a control signal re-converting unit configured to detect the time period from the electrical signal, and convert the electrical signal into a control signal corresponding to the time period.

12. The computing system of claim 11, further comprising a central processing unit (CPU), a user interface, a power supply, and a bus connected to the memory system, the CPU, the user interface, and the power supply.

13. The computing system of claim 11, wherein the control signal is one of a column address signal to address columns of the memory or a row address signal to address rows of the memory.

14. The computing system of claim 13, wherein the time period is a first value when the control signal is a CAS signal and a second and different value when the control signal is a RAS signal.

15. The computing system of claim 13, wherein the control signal re-converting unit comprises a control signal conversion table including respective entries for the CAS signal and the RAS signal and their respective time periods.

16. The computing system of claim 13, wherein n is the same for the CAS signal and RAS signal.

17. The computing system of claim 11, wherein the memory controller and the memory are connected to each other via a waveguide.

18. The computing system of claim 11, wherein the control signal converting unit and the control signal re-converting unit are FPGAs.

19. A memory device comprises:
a memory receiving unit configured to convert an optical signal including a sinusoidal part into an electrical signal, wherein the optical signal comprises n starting bits indicated as n sequential clocks and a target clock activated after a time period has elapsed from a start point of the starting bits; and
a control signal re-converting unit configured to detect the time period from electrical signal, and convert the electrical signal into a control signal corresponding to the time period.

20. The memory device of claim 19, wherein the memory receiving unit comprises a voltage level translator configured to convert a voltage level of the electrical signal into an operation voltage level of the memory.
